(19) United States
(12) Patent Application Publication
(10) Pub. No.: US 2023/0384118 A1
(43) Pub. Date: Nov. 30, 2023

(54) THREE-DIMENSIONAL ROAD NETWORK CONSTRUCTION METHOD AND APPARATUS, ELECTRONIC DEVICE, AND STORAGE MEDIUM

(71) Applicant: BEIJING SOGOU TECHNOLOGY DEVELOPMENT CO., LTD., Beijing (CN)

(72) Inventor: Ran XU, Beijing (CN)

(21) Appl. No.: 18/232,761

(22) Filed: Aug. 10, 2023

Related U.S. Application Data
(63) Continuation of application No. PCT/CN2022/109831, filed on Aug. 3, 2022.

(30) Foreign Application Priority Data
Sep. 29, 2021 (CN) 202111167933.6

(51) Int. Cl. G01C 21/00

(52) U.S. Cl. CPC G01C 21/3822

(57) ABSTRACT

This application provides a three-dimensional road network construction method performed by an electronic device. The method includes: obtaining a two-dimensional road network, the two-dimensional road network comprising a plurality of paths, each path being formed by connecting a plurality of nodes; determining a relative elevation for a node of a current path overlapping the current path and/or another path among the nodes of the current path, the relative elevation representing a height of the current path at the node from a reference plane; determining relative elevations of nodes constituting a center line of the current path according to the relative elevations of the nodes of the current path and a width of the current path; and constructing a three-dimensional road corresponding to the current path according to the width and the relative elevations of the nodes of the center line of the current path to obtain a three-dimensional road network.

### CROSS-REFERENCE TO RELATED APPLICATIONS

This application is a continuation application of PCT Patent Application No. PCT/CN2022/109831, entitled “THREE-DIMENSIONAL ROAD NETWORK CONSTRUCTION METHOD AND APPARATUS, ELECTRONIC DEVICE, STORAGE MEDIUM” filed on Aug. 3, 2022, which claims priority to Chinese Patent Application No. 202111167933.6, entitled “THREE-DIMENSIONAL ROAD NETWORK CONSTRUCTION METHOD AND APPARATUS, ELECTRONIC DEVICE, STORAGE MEDIUM” filed with the China National Intellectual Property Administration on Sep. 29, 2021, all of which is incorporated by reference in its entirety.

### FIELD OF THE TECHNOLOGY

This application relates to the field of computer technologies, and in particular, to a three-dimensional road network construction method and apparatus, an electronic device, and a storage medium.

### BACKGROUND OF THE DISCLOSURE

Maps consisting of road networks are essential for navigation software. As roads in the real world are planar, spatial data structures with three-dimensional interchange relationships and complex spatial topological relationships, there is an urgent need for the navigation software to upgrade the currently used two-dimensional line-type road network to a three-dimensional road network with a high degree of spatial expression.

At present, a three-dimensional road network can be established mainly by using laser point cloud, high-precision real-time kinematic positioning (RTK), and other surveying and mapping technologies. Specifically, surveyors and mappers can carry surveying and mapping tools to the field scene for surveying and mapping, and use high-precision data obtained through surveying and mapping to construct a three-dimensional road network.

However, current solutions are often impractical because they are too slow and/or too expensive to implement.

### SUMMARY

Based on this, this application provides a three-dimensional road network construction solution to resolve the problems mentioned in the background.

This application further provides a three-dimensional road network construction apparatus to ensure actual implementation and application of the foregoing method.

An embodiment of this application provides a three-dimensional road network construction method, performed by an electronic device, the method including:

obtaining a two-dimensional road network, the two-dimensional road network comprising a plurality of paths, each path being formed by connecting a plurality of nodes;

determining a relative elevation for a node of a current path overlapping the current path and/or another path among the nodes of the current path, the relative elevation representing a height of the current path at the node from a reference plane;

determining relative elevations of nodes constituting a center line of the current path according to the relative elevations of the nodes of the current path and a width of the current path; and

constructing a three-dimensional road corresponding to the current path according to the width of the current path and the relative elevations of the nodes of the center line of the current path to obtain a three-dimensional road network.

An embodiment of this application further provides an electronic device, including a memory and one or more programs, the one or more programs being stored in the memory and configured to be executed by one or more processors, and causing the electronic device to perform the aforementioned three-dimensional road network construction methods described above.

An embodiment of this application further provides a non-transitory computer-readable medium, storing instructions, the instructions, when executed by one or more processors of an electronic device, causing the of an electronic device to perform the aforementioned three-dimensional road network construction methods described above.

### BRIEF DESCRIPTION OF THE DRAWINGS

To describe the technical solutions of the embodiments of this application more clearly, the following briefly introduces the accompanying drawings required for describing the embodiments. Apparently, the accompanying drawings in the following description show only some embodiments of this application, and a person of ordinary skill in the art may still derive other drawings from these accompanying drawings without creative efforts.

FIG. 1 is a flowchart of steps of a three-dimensional road network construction method according to an embodiment of this application.

FIG. 2 is a schematic structural diagram of a two-dimensional road network according to an embodiment of this application.

FIG. 3 is a schematic structural diagram of a three-dimensional interchange system according to an embodiment of this application.

FIG. 4 is a schematic structural diagram of a three-dimensional road network according to an embodiment of this application.

FIG. 5 is a flowchart of specific steps of a three-dimensional road network construction method according to an embodiment of this application.

FIG. 6 is a block diagram of a three-dimensional road network construction apparatus according to an embodiment of this application.

FIG. 7 is a block diagram of an electronic device used for constructing a three-dimensional road network according to an exemplary embodiment in this application.

FIG. 8 is a schematic structural diagram of a server according to an embodiment of this application.

### DESCRIPTION OF EMBODIMENTS

The technical solutions in embodiments of this application are clearly and completely described in the following with reference to the accompanying drawings in the embodiments of this application. Apparently, the described embodiments are merely some rather than all of the embodiments of this application. All other embodiments obtained by a person of ordinary skill in the art based on the embodiments of this application without creative efforts fall within the protection scope of this application.

This application can be used in numerous general purpose or special purpose computing apparatus environments or configurations, such as: personal computers, server computers, handheld or portable devices, tablet-type devices, multiprocessor devices, or distributed computing environments that include any of the foregoing apparatuses or devices.

This application can be described in the general context of computer-executable instructions executed by a computer, for example, a program module. Generally, the program module includes a routine, a program, an object, a component, a data structure, and the like for executing a particular task or implementing a particular abstract data type. This application can also be practiced in distributed computing environments in which tasks are performed by remote processing devices that are connected through a communication network. In a distributed computing environment, the program module may be located in both local and remote computer storage mediums including storage devices.

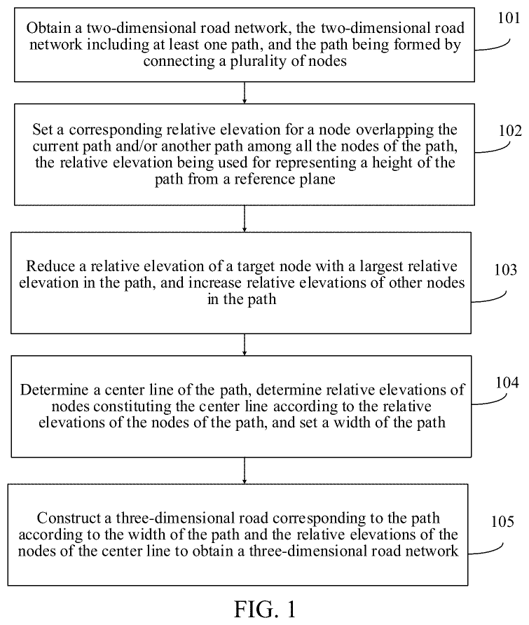

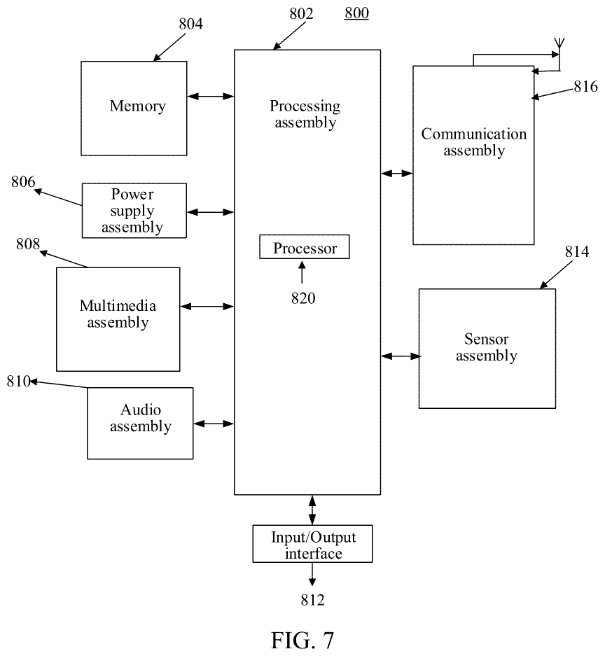

FIG. 1 is a flowchart of steps of a three-dimensional road network construction method according to an embodiment of this application. The method is applicable to a client, or may be performed by an electronic device 800 shown in FIG. 7. As shown in FIG. 1, the method may include the following steps:

Step 101. Obtain a two-dimensional road network, the two-dimensional road network including at least one path, and the path being formed by connecting a plurality of nodes.

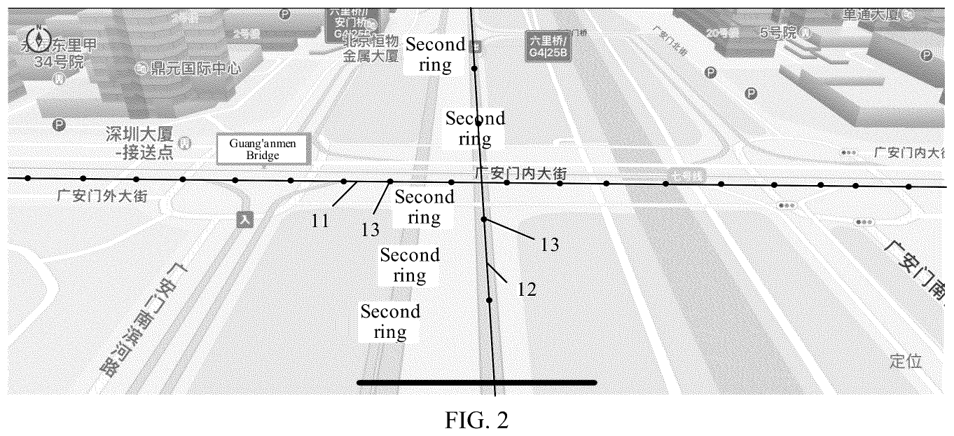

In this embodiment of this application, FIG. 2 is a schematic structural diagram of a two-dimensional road network according to an embodiment of this application. The two-dimensional road network includes a plurality of paths. FIG. 2 shows reference numerals of some paths, that is, a second ring path 12 at ground level, an elevated Guang'anmen Bridge path 11, and a plurality of nodes 13 included in the paths. One path may be used for representing one road. The paths may intersect or overlap each other, or the like. One node 13 may consist of coordinates at a location where the node is located. The two-dimensional road network shows only a topological relationship of paths in a two-dimensional plane, and there is no expression of a path relationship in a height space. Therefore, this is extremely abstract for a user and a viewer of a map, and especially on roads with height changes such as interchange roads, the two-dimensional road network cannot accurately display and guide a road traffic relationship. This embodiment of this application aims to construct a three-dimensional road network based on data of an original two-dimensional road network, so that the three-dimensional road network has a clear and accurate expression of a path relationship in a height space, thereby resolving the foregoing problem.

The two-dimensional road network may be obtained based on actual surveying and mapping, or may be downloaded from a related map database, or may be directly exported from map software. This is not limited in this embodiment of this application.

Step 102. Set a corresponding relative elevation for a node overlapping the current path and/or another path among all the nodes of the path, the relative elevation being used for representing a height of the path from a reference plane.

In this embodiment of this application, in order to construct a three-dimensional road network, height values of nodes included in a path with a height space expression requirement need to be first obtained, so that the path can be expressed in the height space. Specifically, in most cases, the path with the height space expression requirement may be each path in an interchange system. These paths are at a particular height from the ground, intersect and overlap each other, and each have a particular longitudinal slope. The core of this embodiment of this application is the three-dimensional construction of paths in such an interchange system to enable a user and a viewer of a map to accurately display and guide a road traffic relationship in the interchange system.

Further, road construction needs to be carried out in strict accordance with a road design specification, that is, road construction needs to refer to the road design specification for a minimum relative elevation, a maximum longitudinal slope, and other parameters of interchange roads of each level. The relative elevation is used for representing a height of a path from a reference plane (for example, the ground). A relative floor height elevation is used for representing a difference between heights of paths in two adjacent layers in the interchange system at an overlap position. The road design specification has corresponding restrictions on a minimum relative floor height elevation at an overlap position. Therefore, an initial relative elevation of overlapping nodes in a path in this application may be set to a preset value. The preset value meets the minimum relative floor height elevation stipulated in the road design specification. A longitudinal slope refers to a ratio of a difference between heights of two points of the same slope segment on a longitudinal section of a route to a horizontal distance between the two points, expressed as a percentage. The maximum longitudinal slope defines an upper limit of the longitudinal slope of the path.

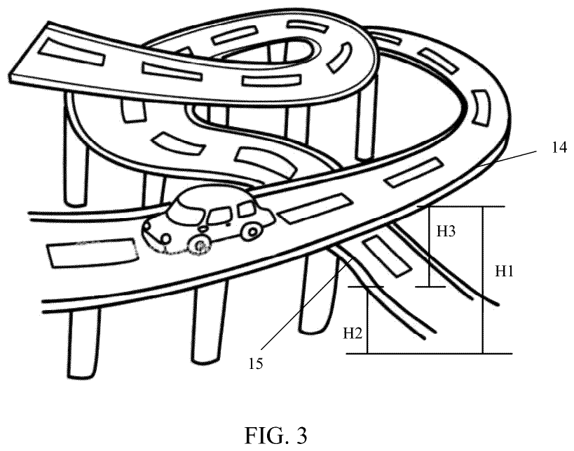

FIG. 3 is a schematic structural diagram of a three-dimensional interchange system according to an embodiment of this application. At a position where an upper-layer path 14 and a lower-layer path 15 overlap, a relative elevation of the upper-layer path 14 is H1, a relative elevation of the lower-layer path 15 is H2, and a relative floor height elevation therebetween is H3=H1−H2.

In this step, a path may overlap the path or another path. Therefore, for a node overlapping the current path and/or another path among all nodes of the path, a relative elevation corresponding to a node in an upper layer of the path may be set according to the restrictions on the minimum relative floor height elevation stipulated in the road design specification, so that a relative floor height elevation of the set overlapping nodes is greater than or equal to the minimum relative floor height elevation stipulated in the road design specification.

Step 103. Reduce a relative elevation of a target node with a largest relative elevation in the path, and increase relative elevations of other nodes in the path.

A node closer to the target node among the other nodes has a more greatly increased relative elevation.

In step 102, the relative elevation of the node in which overlapping occurs in the path is set (a relative elevation of another node in which no overlapping occurs is initially set to 0). In this step, specifically, a target node with a largest relative elevation in the path may be found first, and the relative elevation of the target node in the path is transferred to other nodes on both sides in a smooth descending manner, that is, the relative elevation of the target node is reduced and relative elevations of the other nodes are increased, so that a node closer to the target node among the other nodes has a more greatly increased relative elevation.

In this embodiment of this application, roads in the interchange system each have a particular longitudinal slope. Based on the consideration of driving safety, the slopes of the roads are gently rising or falling, and sharply rising or falling slopes are more likely to cause traffic safety accidents. In the display of a three-dimensional road, the three-dimensional road also needs to be displayed in a smooth slope to improve realism of the three-dimensional display of the road. Therefore, the relative elevation of each node in the path also needs to drop smoothly from the target node with the largest relative elevation to the other nodes on both sides, to further meet a requirement on a relative floor height elevation between roads in the upper and lower layers while meeting a gentle slope requirement of the road.

For example, a path consists of: node 1 (with a relative elevation of 0), node 2 (with a relative elevation of 0), node 3 (with a relative elevation of 50), node 4 (with a relative elevation of 0), and node 5 (with a relative elevation of 0) connected in sequence. To meet a gentle slope requirement and a requirement on a relative floor height elevation with a path in another layer, the relative elevation of the node 3 with the largest relative elevation may be transferred to both sides in a smooth descending manner. A path after the transfer consists of: node 1 (with a relative elevation of 5), node 2 (with a relative elevation of 10), node 3 (with a relative elevation of 20), node 4 (with a relative elevation of 10), and node 5 (with a relative elevation of 5).

Step 104. Determine a center line of the path, determine relative elevations of nodes constituting the center line according to the relative elevations of the nodes of the path, and set a width of the path.

In this embodiment of this application, each actual road has a center line, and the center line is a line extending along the center of the road. Therefore, the center line of the road may be used as a reference to further set a width of the road, and set relative elevations of nodes of the center line to relative elevations of nodes corresponding to the nodes of the center line among all nodes of the path, so that in a subsequent three-dimensional path construction process, a three-dimensional road may be drawn based on the center line of the path, the relative elevations of the nodes of the center line, and the width of the path.

Step 105. Construct a three-dimensional road corresponding to the path according to the width of the path and the relative elevations of the nodes of the center line to obtain a three-dimensional road network.

In this step, according to the width of the path and the relative elevations of the nodes of the center line of the path, on the basis of rendering a road with a width feature, a height space of the road may be further accurately expressed through the relative elevations of the nodes of the center line, so that the three-dimensional road corresponding to the path is constructed. Nodes at different positions of the center line of the road may have different relative elevations. In this case, an elevation of the center line is used as a rendering basis of the height space. Therefore, intersection and overlapping relationships between roads in each layer in the interchange system can be accurately expressed, and slope changes of the roads in the height space are also expressed, thereby improving accuracy of a map to express a topological relationship of roads, enabling a user and a viewer of the map to accurately display and guide a road traffic relationship in the interchange system.

Further, in this embodiment of this application, the three-dimensional road network is constructed based on information provided by the original two-dimensional road network, without the need to use expensive surveying and mapping devices or carry out a large amount of cumbersome manual field surveying and mapping, and ensures accuracy and intuitiveness of a topological relationship of roads in the height space, thereby providing a low-cost solution to display a three-dimensional topological relationship of the roads.

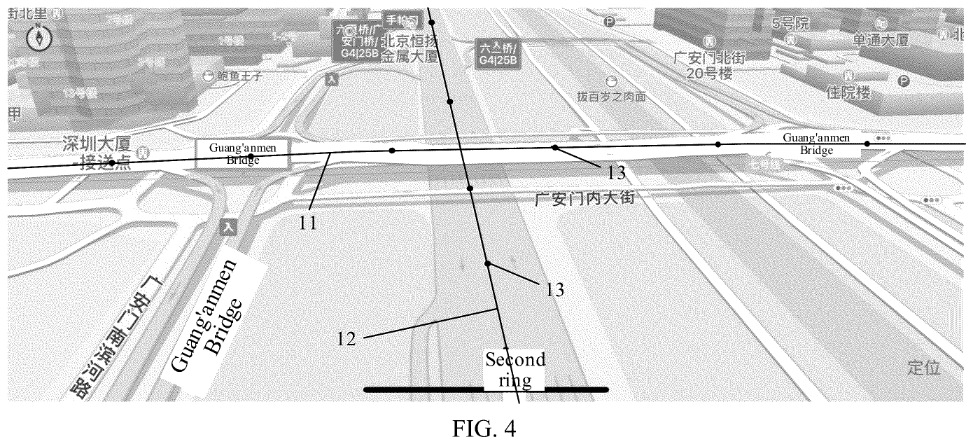

For example, FIG. 4 is a schematic structural diagram of a three-dimensional road network according to an embodiment of this application. The three-dimensional road network in FIG. 4 is converted from the two-dimensional road network in FIG. 2. The three-dimensional road network is obtained through rendering based on the width of the path in the two-dimensional road network in FIG. 2 and the relative elevations of the nodes of the center line of the path. Therefore, it can be learned that in FIG. 4, a topological relationship between the second ring path 12 on the ground and an elevated Guang'anmen Bridge path 11 is expressed in the height space. Through shadow rendering of a height drop of the Guang'anmen Bridge path 11, a user can intuitively see an actual case in which the Guang'anmen Bridge path 11 is elevated above the ground.

In summary, in the three-dimensional road network construction method according to this embodiment of this application, according to the width of the path and mapping of the relative elevations of the nodes of the center line of the path, on the basis of rendering a road with a width feature, a three-dimensional road corresponding to the path can be further constructed. The three-dimensional road can accurately express intersection and overlapping relationships between roads in each layer in the interchange system, and slope changes of the roads in the height space are also expressed, thereby improving accuracy of a map to express a topological relationship of roads, enabling a user and a viewer of the map to accurately display and guide a road traffic relationship in the interchange system. In this embodiment of this application, the three-dimensional road network is constructed based on information provided by the original two-dimensional road network, without the need to use expensive surveying and mapping devices or carry out a large amount of cumbersome manual field surveying and mapping, and ensures accuracy and intuitiveness of a topological relationship of roads in the height space.

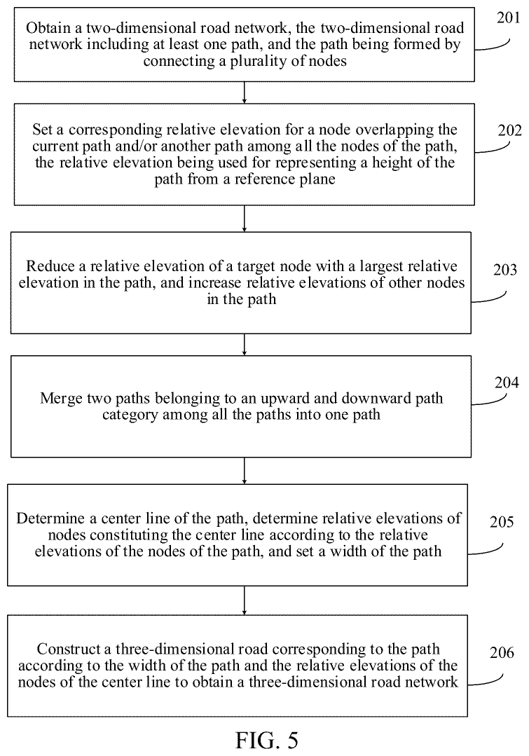

FIG. 5 is a flowchart of specific steps of a three-dimensional road network construction method according to an embodiment of this application. As shown in FIG. 5, the method may include the following steps:

Step 201. Obtain a two-dimensional road network, the two-dimensional road network including at least one path, and the path being formed by connecting a plurality of nodes.

For this step, refer to the foregoing step 101 for details, which are not described herein again.

Step 202. Set a corresponding relative elevation for a node overlapping the current path and/or another path among all the nodes of the path, the relative elevation being used for representing a height of the path from a reference plane.

For this step, refer to the foregoing step 102 for details, which are not described herein again.

Step 203. Reduce a relative elevation of a target node with a largest relative elevation in the path, and increase relative elevations of other nodes in the path.

A node closer to the target node among the other nodes has a more greatly increased relative elevation.

For this step, refer to the foregoing step 103 for details, which are not described herein again.

The path is provided with a corresponding maximum longitudinal slope, and after the relative elevation of the target node with the largest relative elevation in the path is reduced and the relative elevations of the other nodes in the path are increased, a longitudinal slope of the path is less than or equal to the maximum longitudinal slope.

In this embodiment of this application, road construction needs to refer to a road design specification for a maximum longitudinal slope and other parameters of interchange roads of each level, so that an actual longitudinal slope of a road needs to be less than the correspondingly set maximum longitudinal slope, thereby ensuring safety of a vehicle going up and down slopes. Therefore, after the relative elevation of the target node with the largest relative elevation in the path is transferred to other nodes on both sides in a smooth descending manner, it needs to detect whether a longitudinal slope of the path after the transfer is less than or equal to the maximum longitudinal slope. If the longitudinal slope of the path is less than or equal to the maximum longitudinal slope, it is considered that requirements of related regulations of the road design specification on the longitudinal slope of the road are met. If the longitudinal slope of the path is greater than the maximum longitudinal slope, it is considered that the slope is extremely steep, and it needs to further readjust a smooth decrease value of the relative elevation of the target node toward other nodes to finally make the longitudinal slope of the path less than or equal to the maximum longitudinal slope.

Step 204. Merge two paths belonging to an upward and downward path category among all the paths into one path.

Step 204 may specifically include the following steps:

Substep 2041. Obtain road names, road grades, point sequence directions, and geometric forms of the paths.

Substep 2042. In a case that two of the paths have the same road names, the same road grades, opposite point sequence directions, and parallel geometric forms, determine that the two paths belong to the upward and downward path category.

Substep 2043. Merge the two paths into one path.

During actual application, there is a type of road referred to as an upward and downward road. Such a road usually consists of two paths with opposite travel directions, such as an upward path and a downward path of an expressway, its center line overlaps a side on which the two paths connect to each other, and green belts, double solid lines, barriers, and the like are usually provided at the center line, so that the upward and downward road may be split into two paths with opposite travel directions. For attributes of the two paths, only the travel directions are different and other attributes are the same. In this embodiment of this application, the two paths may be merged into the same path, so that the merged path can be subsequently used to directly construct a three-dimensional path, thereby reducing a calculation amount during the construction of the three-dimensional path.

In this embodiment of this application, two paths that belong to the upward and downward path category and that can be merged into one path usually have features of the same road names, the same road grades, opposite point sequence directions, and parallel geometric forms. Therefore, a road name, a road grade, a point sequence direction, and a geometric form of each path may be obtained, and two of the paths having the same road name, the same road grade, opposite point sequence directions, and parallel geometric forms are determined as paths belonging to the upward and downward path category, so that the two paths are merged into one path for subsequent construction of a three-dimensional path.

Step 205. Determine a center line of the path, determine relative elevations of nodes constituting the center line according to the relative elevations of the nodes of the path, and set a width of the path.

For this step, refer to the foregoing step 104 for details, which are not described herein again.

Step 205 may specifically include the following steps:

Substep 2051. In a case that the path is obtained without merging paths, set the relative elevations of the nodes of the center line to relative elevations of nodes in the path that correspond to the nodes of the center line.

In this embodiment of this application, according to the width of the path and the relative elevations of the nodes of the center line of the path, on the basis of rendering a road with a width feature, a height space of the road may be further accurately expressed through the relative elevations of the nodes of the center line, so that the three-dimensional road corresponding to the path is constructed. Therefore, during the construction of the three-dimensional road, the relative elevations of the nodes of the center line may be used as an elevation reference of the three-dimensional road in the height space. Specifically, when the path is obtained without merging paths, for example, the path is obtained not by merging two paths belonging to the upward and downward path category, the relative elevations of the nodes of the center line may be directly set to the relative elevations of the nodes in the path that correspond to the nodes of the center line. For example, a relative elevation of a node at a 500-meter location of the path is 60. In this case, a relative elevation of a node at a 500-meter location of the center line of the path may also be mapped to 60.

Substep 2052. In a case that the path is obtained by merging paths, set the relative elevations of the nodes of the center line to larger relative elevations of two nodes corresponding to the nodes of the center line in the two paths before the merging.

Specifically, when the path is obtained by merging paths, for example, the path is obtained by merging two paths belonging to the upward and downward path category, the relative elevations of the nodes of the center line may be set to larger relative elevations of two nodes corresponding to the nodes of the center line in the two paths before the merging. For example, relative elevations of nodes at 500-meter locations of the two paths before the merging are respectively 60 and 80. In this case, a relative elevation of a node at a 500-meter location of the center line of the path may be mapped to the larger value 80.

Step 205 may specifically include the following steps:

Substep 2053. Obtain the number of lanes of the path.

Substep 2054. Use a product of the number of lanes of the path and a preset single lane width as the width of the path.

Specifically, the width of the path may be designed according to a design requirement on a road width in the road design specification. For the setting of the width of the path, the specification specifically defines a single lane width of a road, that is, when the number of lanes of the current path is obtained, the product of the number of lanes of the path and the preset single lane width may be used as the width of the path.

In some special nodes of the road, corresponding widths may be further set in a targeted manner, that is, corresponding road widths are set at some special nodes on the center line of the path according to the road design specification. For example, a turning node corresponds to a width that meets the specification, and a node in a road functional area (such as a temporary auxiliary road) corresponds to a width that meets the specification. In addition, when the width of the road changes, the change in the width of the road is smoothed at a location where the width of the road changes to meet a specification requirement.

Step 206. Construct a three-dimensional road corresponding to the path according to the width of the path and the relative elevations of the nodes of the center line to obtain a three-dimensional road network.

For this step, refer to the foregoing step 105 for details, which are not described herein again.

The method may further include the following steps:

Step 207. Determine an endpoint node in the path for connection to another path.

In this embodiment of this application, in order to form a road network, paths need to be connected to each other. Therefore, an endpoint node in a path for connection to another path needs to be identified. The endpoint node may be an end node in the path (except for an end node of a dead-end road).

Step 208. In a case that a relative elevation of the endpoint node is less than a relative elevation of an endpoint node of the other path for connection, set the relative elevation of the endpoint node of the path to the relative elevation of the endpoint node of the other path for connection.

Specifically, during connection of an endpoint node of a path to an endpoint node of another path, relative elevations of the two need to be set to be the same, to avoid a case that the nodes cannot be connected due to different elevations. In a case that the relative elevation of the endpoint node is less than the relative elevation of the endpoint node of the other path for connection, the relative elevation of the endpoint node of the path may be set to the larger relative elevation of the endpoint node of the other path for connection. For example, if an endpoint node A (with a relative elevation of 20) of the path is to be connected to an endpoint node B (with a relative elevation of 40) of another path, the relative elevation of the endpoint node A is changed from 20 to 40, so that the two nodes are connected after the relative elevations of the two remain the same.

Step 209. In a case that a relative elevation of the endpoint node is greater than a relative elevation of an endpoint node of the other path for connection, set the relative elevation of the endpoint node of the other path for connection to the relative elevation of the endpoint node of the path.

In this step, when the relative elevation of the endpoint node is greater than the relative elevation of the endpoint node of the other path for connection, the relative elevation of the endpoint node of the other path for connection may be set to the relative elevation of the endpoint node of the path. For example, if an endpoint node A (with a relative elevation of 30) of the path is to be connected to an endpoint node B (with a relative elevation of 10) of another path, the relative elevation of the endpoint node B is changed from 10 to 30, so that the two nodes are connected after the relative elevations of the two remain the same.

After step 203, the method may further include the following step:

Step 210. In a case that a relative floor height elevation of the node overlapping the current path and/or another path in the path is less than a preset minimum relative floor height elevation, add a relative elevation of a node located in an upper layer at an overlap position by the minimum relative floor height elevation.

The relative floor height elevation is used for representing a difference between heights of paths in two adjacent layers from the reference plane.

In this embodiment of this application, the relative floor height elevation is used for representing a difference between heights of paths in two adjacent layers in the interchange system at an overlap position. The road design specification has corresponding restrictions on a minimum relative floor height elevation at an overlap position. By referring to a value of the minimum relative floor height elevation of the road design specification, a view of the generated three-dimensional road network can relatively accurately reflect a distribution status of actual roads in reality.

After the relative elevation of the target node with the largest relative elevation in the path is reduced and the relative elevations of the other nodes in the path are increased, to case the relative elevation of the target node in the path to be transferred to other nodes on both sides in a smooth descending manner, it needs to be further determined whether a relative floor height elevation of the node overlapping the current path and/or another path in the path is less than a preset minimum relative floor height elevation. If the relative floor height elevation is less than the minimum relative floor height elevation, it indicates that a height space between roads in an upper and lower layers at the overlapping node location of the current path is insufficient, and it may be difficult to distinguish an overlapping relationship between the roads in the upper and lower layers during three-dimensional display. In this case, a relative elevation of a node located in the upper layer at the overlap position may be added by the minimum relative floor height elevation, to distinguish the overlapping relationship between the roads in the upper and lower layers as clearly as possible during the three-dimensional display.

In this embodiment of this application, step 208, step 209, and step 210 are all performed after step 203. Therefore, after the relative elevation of the node with the largest relative elevation in the path is smoothly transferred to both sides in step 203, the relative elevations of the nodes in the path may change due to actions performed in step 208, step 209, and step 210. If the relative elevations of the nodes in the path change after step 208 or step 209 or step 210, slope smoothness of the path changes accordingly, resulting in failure to meet the requirements of the road design specification. In this case, step 203 may be performed again to cyclically perform the action of smoothly transferring the relative elevation of the node with the largest relative elevation in the path to both sides, to ensure that the requirement on the slope smoothness of the path is met.

After step 205, the method may further include the following step:

Step 211. Reduce a relative elevation of a node with a largest relative elevation in the center line, and increase relative elevations of other nodes in the center line, a node in the other nodes that is closer to the node with the largest relative elevation in the center line having a more greatly increased relative elevation.

The path is provided with a corresponding maximum longitudinal slope, and after the relative elevation of the node with the largest relative elevation in the center line is reduced and the relative elevations of the other nodes in the center line are increased, a longitudinal slope of the center line is less than or equal to the maximum longitudinal slope.

In this embodiment of this application, the height space of the road is accurately expressed based on the nodes of the center line to construct the three-dimensional road corresponding to the path. Therefore, in this embodiment of this application, the relative elevation of the node with the largest elevation in the center line may be further transferred to other nodes on both sides in a smooth descending manner, that is, the relative elevation of the node with the largest relative elevation in the center line is reduced, and the relative elevations of the other nodes in the center line are increased.

Roads in the interchange system each have a particular longitudinal slope. Based on the consideration of driving safety, the slopes of the roads are gently rising or falling, and sharply rising or falling slopes are more likely to cause traffic safety accidents. Therefore, the relative elevations of the nodes in the center line of the path also need to drop smoothly from the node with the largest relative elevation to the other nodes on both sides, to further meet a requirement on a relative floor height elevation between roads in the upper and lower layers while meeting a gentle slope requirement of the road.

After step 206, the method may further include the following steps:

Step 212. Obtain a topological connectivity relationship between the paths and traffic marking attributes of the nodes of the path.

In this embodiment of this application, the two-dimensional road network includes the topological connectivity relationship between the paths and the traffic marking attributes of the nodes of the path. The topological connectivity relationship between the paths is used for representing a connectivity relationship between the paths. The traffic marking attributes are used for representing traffic markings at the location to provide traffic safety instructions.

Step 213. Connect the three-dimensional roads according to the topological connectivity relationship.

In this step, the constructed three-dimensional roads may be connected according to the topological connectivity relationship between the paths to form an initial three-dimensional road network.

Step 214. Set traffic markings at corresponding locations in the three-dimensional road according to the traffic marking attributes of the nodes of the path.

In this step, traffic markings are set at corresponding locations in the three-dimensional road according to the traffic marking attributes of the nodes of the path, so that traffic safety signs can be indicated at the corresponding locations in the three-dimensional road network to improve the richness of useful information in the three-dimensional road network.

In summary, in the three-dimensional road network construction method according to this embodiment of this application, according to the width of the path and mapping of the relative elevations of the nodes of the center line of the path, on the basis of rendering a road with a width feature, a three-dimensional road corresponding to the path can be further constructed. The three-dimensional road can accurately express intersection and overlapping relationships between roads in each layer in the interchange system, and slope changes of the roads in the height space are also expressed, thereby improving accuracy of a map to express a topological relationship of roads, enabling a user and a viewer of the map to accurately display and guide a road traffic relationship in the interchange system. In this embodiment of this application, the three-dimensional road network is constructed based on information provided by the original two-dimensional road network, without the need to use expensive surveying and mapping devices or carry out a large amount of cumbersome manual field surveying and mapping, and ensures accuracy and intuitiveness of a topological relationship of roads in the height space.

For ease of description, the foregoing method embodiments are stated as a combination of a series of actions. However, a person skilled in the art is to know that this application is not limited by the described action sequence, because according to this application, some steps may be performed in another sequence or simultaneously. In addition, a person skilled in the art is further to understand that the embodiments described in this specification are all exemplary embodiments, and the involved actions and modules are not necessarily required by this application.

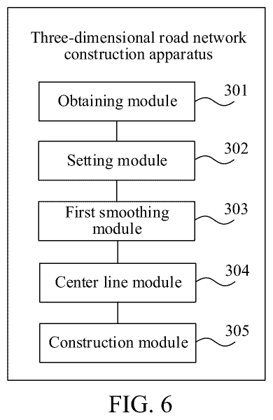

Corresponding to the method provided in the foregoing embodiment of the three-dimensional road network construction method of this application, referring to FIG. 6, this application further provides an embodiment of a three-dimensional road network construction apparatus. In this embodiment, The apparatus may include:

an obtaining module 301, configured to obtain a two-dimensional road network, the two-dimensional road network including at least one path, and the path being formed by connecting a plurality of nodes;

a setting module 302, configured to set a corresponding relative elevation for a node overlapping the current path and/or another path among all the nodes of the path, the relative elevation being used for representing a height of the path from a reference plane;

a first smoothing module 303, configured to reduce a relative elevation of a target node with a largest relative elevation in the path, and increasing relative elevations of other nodes in the path, a node closer to the target node among the other nodes having a more greatly increased relative elevation;

a center line module 304, configured to determine a center line of the path, determine relative elevations of nodes constituting the center line according to the relative elevations of the nodes of the path, and set a width of the path; and

a construction module 305, configured to construct a three-dimensional road corresponding to the path according to the width of the path and the relative elevations of the nodes of the center line to obtain a three-dimensional road network.

The path is provided with a corresponding maximum longitudinal slope, and after the relative elevation of the target node with the largest relative elevation in the path is reduced and the relative elevations of the other nodes in the path are increased, a longitudinal slope of the path is less than or equal to the maximum longitudinal slope.

The apparatus further includes:

an endpoint module, configured to determine an endpoint node in the path for connection to another path; and

a first adjustment module, configured to: when a relative elevation of the endpoint node is less than a relative elevation of an endpoint node of the other path for connection, set the relative elevation of the endpoint node of the path to the relative elevation of the endpoint node of the other path for connection; and

a second adjustment module, configured to: when a relative elevation of the endpoint node is greater than a relative elevation of an endpoint node of the other path for connection, set the relative elevation of the endpoint node of the other path for connection to the relative elevation of the endpoint node of the path.

The apparatus further includes:

a third adjustment module, configured to: when a relative floor height elevation of the node overlapping the current path and/or another path in the path is less than a preset minimum relative floor height elevation, add a relative elevation of a node located in an upper layer at an overlap position by the minimum relative floor height elevation, the relative floor height elevation being used for representing a difference between heights of paths in two adjacent layers from the reference plane.

Before the center line of the path is determined, the apparatus further includes:

a merge module, configured to merge two paths belonging to an upward and downward path category among all the paths into one path.

The merge module includes:

an obtaining submodule, configured to obtain road names, road grades, point sequence directions, and geometric forms of the paths;

a determining submodule, configured to: when two of the paths have the same road names, the same road grades, opposite point sequence directions, and parallel geometric forms, determine that the two paths belong to the upward and downward path category; and

a merge submodule, configured to merge the two paths into one path.

The center line module includes:

a first adjustment submodule, configured to: when the path is obtained without merging paths, set the relative elevations of the nodes of the center line to relative elevations of nodes in the path that correspond to the nodes of the center line; and

a second adjustment submodule, configured to: when the path is obtained by merging paths, set the relative elevations of the nodes of the center line to larger relative elevations of two nodes corresponding to the nodes of the center line in the two paths before the merging.

The apparatus further includes:

a second smoothing module, configured to reduce a relative elevation of a node with a largest relative elevation in the center line, and increase relative elevations of other nodes in the center line, a node in the other nodes that is closer to the node with the largest relative elevation in the center line having a more greatly increased relative elevation;

the path being provided with a corresponding maximum longitudinal slope, and after the relative elevation of the node with the largest relative elevation in the center line is reduced and the relative elevations of the other nodes in the center line are increased, a longitudinal slope of the center line being less than or equal to the maximum longitudinal slope.

The center line module includes:

a quantity submodule, configured to obtain the number of lanes of the path; and

a product module, configured to use a product of the number of lanes of the path and a preset single lane width as the width of the path.

The apparatus further includes:

an attribute module, configured to obtain a topological connectivity relationship between the paths and traffic marking attributes of the nodes of the path;

a connection module, configured to connect the three-dimensional roads according to the topological connectivity relationship; and

a marking module, configured to set traffic markings at corresponding locations in the three-dimensional road according to the traffic marking attributes of the nodes of the path.

In summary, for the three-dimensional road network construction apparatus according to this embodiment of this application, according to the width of the path and mapping of the relative elevations of the nodes of the center line of the path, on the basis of rendering a road with a width feature, a three-dimensional road corresponding to the path can be further constructed. The three-dimensional road can accurately express intersection and overlapping relationships between roads in each layer in the interchange system, and slope changes of the roads in the height space are also expressed, thereby improving accuracy of a map to express a topological relationship of roads, enabling a user and a viewer of the map to accurately display and guide a road traffic relationship in the interchange system. In this embodiment of this application, the three-dimensional road network is constructed based on information provided by the original two-dimensional road network, without the need to use expensive surveying and mapping devices or carry out a large amount of cumbersome manual field surveying and mapping, and ensures accuracy and intuitiveness of a topological relationship of roads in the height space.

The specific manners of performing operations by the various modules of the apparatus in the foregoing embodiment are described in detail in the embodiment related to the method, and are not further described in detail herein.

FIG. 7 is a block diagram of an electronic device 800 according to an exemplary embodiment. For example, the electronic device 800 may be a mobile phone, a computer, a digital broadcasting terminal, a messaging device, a game console, a tablet device, a medical device, a fitness facility, a personal digital assistant, or the like.

Referring to FIG. 7, the electronic device 800 may include one or more of the following assemblies: a processing assembly 802, a memory 804, a power supply assembly 806, a multimedia assembly 808, an audio assembly 810, an input/output (I/O) interface 812, a sensor assembly 814, and a communication assembly 816.

The processing assembly 802 usually controls overall operations of the electronic device 800. The memory 804 is configured to store various types of data to support operations on the electronic device 800. The power supply assembly 806 supplies power to various assemblies of the electronic device 800. The multimedia assembly 808 includes a screen providing an output interface between the electronic device 800 and a user. The audio assembly 810 is configured to output and/or input an audio signal. The I/O interface 812 provides an interface between the processing assembly 802 and an external interface module. The external interface module may be a keyboard, a click wheel, buttons, or the like. The sensor assembly 814 includes one or more sensors, configured to provide status evaluation from various aspects to the electronic device 800. The communication assembly 816 is configured to facilitate communication in a wired or wireless manner between the electronic device 800 and other devices.

In an exemplary embodiment, the electronic device 800 may be implemented by one or more application-specific integrated circuits (ASICs), digital signal processors (DSPs), digital signal processing devices (DSPDs), programmable logic devices (PLDs), field programmable gate arrays (FPGAs), controllers, microcontrollers, microprocessors, or other electronic elements, to perform the foregoing method.

In an exemplary embodiment, a non-transitory computer-readable storage medium including instructions is further provided, for example, the memory 804 including instructions. The instructions may be executed by a processor 820 of the electronic device 800 to accomplish the method described above. For example, the non-transitory computer-readable storage medium may be a ROM, a random access memory (RAM), a CD-ROM, a magnetic tape, a floppy disk, an optical data storage device, or the like.

This embodiment of this application includes: According to the width of the path and mapping of the relative elevations of the nodes of the center line of the path, on the basis of rendering a road with a width feature, a three-dimensional road corresponding to the path can be further constructed. The three-dimensional road can accurately express intersection and overlapping relationships between roads in each layer in the interchange system, and slope changes of the roads in the height space are also expressed, thereby improving accuracy of a map to express a topological relationship of roads, enabling a user and a viewer of the map to accurately display and guide a road traffic relationship in the interchange system. In this embodiment of this application, the three-dimensional road network is constructed based on information provided by the original two-dimensional road network, without the need to use expensive surveying and mapping devices or carry out a large amount of cumbersome manual field surveying and mapping, and ensures accuracy and intuitiveness of a topological relationship of roads in the height space.

A non-transitory computer-readable storage medium is provided. When instructions in the storage medium are executed by a processor of a mobile terminal, the mobile terminal is enabled to perform a three-dimensional road network construction method. The method includes:

obtaining a two-dimensional road network, the two-dimensional road network including at least one path, and the path being formed by connecting a plurality of nodes;

setting a corresponding relative elevation for a node overlapping the current path and/or another path among all the nodes of the path, the relative elevation being used for representing a height of the path from a reference plane;

reducing a relative elevation of a target node with a largest relative elevation in the path, and increasing relative elevations of other nodes in the path, a node closer to the target node among the other nodes having a more greatly increased relative elevation;

determining a center line of the path, determining relative elevations of nodes constituting the center line according to the relative elevations of the nodes of the path, and setting a width of the path; and

constructing a three-dimensional road corresponding to the path according to the width of the path and the relative elevations of the nodes of the center line to obtain a three-dimensional road network.

The path is provided with a corresponding maximum longitudinal slope, and after the relative elevation of the target node with the largest relative elevation in the path is reduced and the relative elevations of the other nodes in the path are increased, a longitudinal slope of the path is less than or equal to the maximum longitudinal slope.

The method further includes:

determining an endpoint node in the path for connection to another path; and

when a relative elevation of the endpoint node is less than a relative elevation of an endpoint node of the other path for connection, setting the relative elevation of the endpoint node of the path to the relative elevation of the endpoint node of the other path for connection; or

when a relative elevation of the endpoint node is greater than a relative elevation of an endpoint node of the other path for connection, setting the relative elevation of the endpoint node of the other path for connection to the relative elevation of the endpoint node of the path.

After the reducing a relative elevation of a target node with a largest relative elevation in the path, and increasing relative elevations of other nodes in the path, the method further includes:

when a relative floor height elevation of the node overlapping the current path and/or another path in the path is less than a preset minimum relative floor height elevation, adding a relative elevation of a node located in an upper layer at an overlap position by the minimum relative floor height elevation, the relative floor height elevation being used for representing a difference between heights of paths in two adjacent layers from the reference plane.

Before the determining a center line of the path, the method further includes:

merging two paths belonging to an upward and downward path category among all the paths into one path.

The merging two paths belonging to an upward and downward path category among all the paths into one path includes:

obtaining road names, road grades, point sequence directions, and geometric forms of the paths;

when two of the paths have the same road names, the same road grades, opposite point sequence directions, and parallel geometric forms, determining that the two paths belong to the upward and downward path category; and merging the two paths into one path.

The determining relative elevations of nodes constituting the center line according to the relative elevations of the nodes of the path includes:

when the path is obtained without merging paths, setting the relative elevations of the nodes of the center line to relative elevations of nodes in the path that correspond to the nodes of the center line; or

when the path is obtained by merging paths, setting the relative elevations of the nodes of the center line to larger relative elevations of two nodes corresponding to the nodes of the center line in the two paths before the merging.

After the determining relative elevations of nodes constituting the center line according to the relative elevations of the nodes of the path, the method further includes:

reducing a relative elevation of a node with a largest relative elevation in the center line, and increasing relative elevations of other nodes in the center line, a node in the other nodes that is closer to the node with the largest relative elevation in the center line having a more greatly increased relative elevation;

the path being provided with a corresponding maximum longitudinal slope, and after the relative elevation of the node with the largest relative elevation in the center line is reduced and the relative elevations of the other nodes in the center line are increased, a longitudinal slope of the center line being less than or equal to the maximum longitudinal slope.

The setting a width of the path includes:

obtaining the number of lanes of the path; and

using a product of the number of lanes of the path and a preset single lane width as the width of the path.

After the constructing a three-dimensional road corresponding to the path according to the width of the path and the relative elevations of the nodes of the center line to obtain a three-dimensional road network, the method further includes:

obtaining a topological connectivity relationship between the paths and traffic marking attributes of the nodes of the path;

connecting the three-dimensional roads according to the topological connectivity relationship; and

setting traffic markings at corresponding locations in the three-dimensional road according to the traffic marking attributes of the nodes of the path.

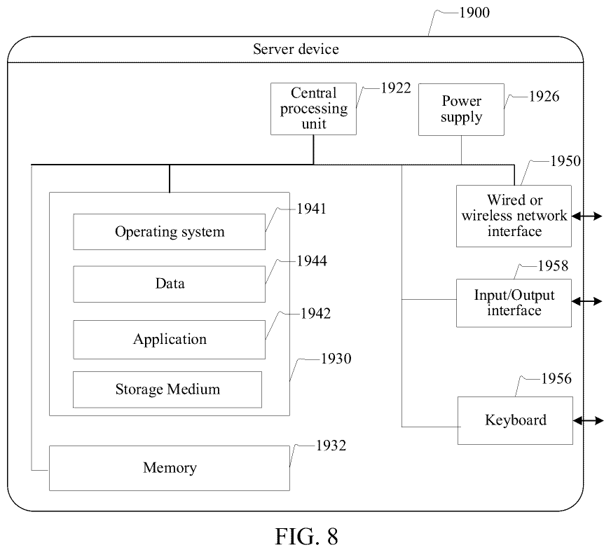

FIG. 8 is a schematic structural diagram of a server according to an embodiment of this application. The server 1900 may vary greatly with different configurations or performance, and may include one or more central processing units (CPUs) 1922 (for example, one or more processors), a memory 1932, and one or more storage mediums 1930 (for example, one or more mass storage devices) storing an application 1942 or data 1944. The memory 1932 and the storage medium 1930 may be temporary storage or persistent storage. A program stored in the storage medium 1930 may include one or more modules (not shown), and each module may include a series of instructions and operations for the server. Further, the CPU 1922 may be configured to communicate with the storage medium 1930, and execute a series of instructions and operations in the storage medium 1930 on the server 1900.

The server 1900 may further include one or more power supplies 1926, one or more wired or wireless network interfaces 1950, one or more input/output interfaces 1958, one or more keyboards 1956, and/or one or more operating systems 1941, for example, Windows Server™, Mac OS X™, Unix™, Linux™, and FreeBSD™.

A person skilled in the art can easily figure out another implementation of this application after considering this specification and practicing this application disclosed herein. This application is intended to cover any variation, use, or adaptive change of this application. These variations, uses, or adaptive changes follow the general principles of this application and include common general knowledge or common technical means, which are not disclosed in the present disclosure, in the art. This specification and the embodiments are considered as merely exemplary, and the real scope and spirit of this application are pointed out in the following claims.

It is to be understood that this application is not limited to the precise structures described above and shown in the accompanying drawings, and various modifications and changes can be made without departing from the scope of this application. The scope of this application is defined only by the appended claims.

In this application, the term “module” in this application refers to a computer program or part of the computer program that has a predefined function and works together with other related parts to achieve a predefined goal and may be all or partially implemented by using software, hardware (e.g., processing circuitry and/or memory configured to perform the predefined functions), or a combination thereof. Each module can be implemented using one or more processors (or processors and memory). Likewise, a processor (or processors and memory) can be used to implement one or more modules. Moreover, each module can be part of an overall module that includes the functionalities of the module. The foregoing descriptions are merely embodiments of this application, and are not intended to limit this application. Any modification, equivalent replacement, improvement and the like made within the spirit and principle of this application shall fall within the protection scope of this application.

What is claimed is:

1. A three-dimensional road network construction method performed by an electronic device, the method comprising:
obtaining a two-dimensional road network, the two-dimensional road network comprising a plurality of paths, each path being formed by connecting a plurality of nodes;
determining a relative elevation for a node of a current path overlapping the current path and/or another path among the nodes of the current path, the relative elevation representing a height of the current path at the node from a reference plane;
determining relative elevations of nodes constituting a center line of the current path according to the relative elevations of the nodes of the current path and a width of the current path; and
constructing a three-dimensional road corresponding to the current path according to the width of the current path and the relative elevations of the nodes of the center line of the current path to obtain a three-dimensional road network.

2. The method according to claim 1, wherein the method further comprises:
determining an endpoint node in the current path for connection to another path; and
when a relative elevation of the endpoint node is less than a relative elevation of an endpoint node of the another path for connection, setting the relative elevation of the endpoint node of the path to the relative elevation of the endpoint node of the another path for connection; or
when a relative elevation of the endpoint node is greater than a relative elevation of an endpoint node of the another path for connection, setting the relative elevation of the endpoint node of the another path for connection to the relative elevation of the endpoint node of the path.

3. The method according to claim 1, wherein before the determining relative elevations of nodes constituting a center line of the current path, the method further comprises:
merging two paths belonging to an upward and downward path category among all the paths into one path.

4. The method according to claim 1, wherein the method further comprises:
adjusting relative elevations of nodes of the current path, wherein the adjusted relative elevations form a longitudinal slope of the current path that is less than or equal to a maximum longitudinal slope.

5. The method according to claim 4, wherein the adjusting relative elevations of nodes of the current path further comprises:
reducing a relative elevation of a target node with a largest relative elevation in the current path, and increasing relative elevations of other nodes in the current path, wherein a node closer to the target node has a more increased relative elevation than the other nodes.

6. The method according to claim 1, wherein after the constructing a three-dimensional road corresponding to the current path according to the width of the current path and the relative elevations of the nodes of the center line of the current path to obtain a three-dimensional road network, the method further comprises:
obtaining a topological connectivity relationship between the plurality of paths and traffic marking attributes of the nodes of the plurality of paths;
connecting the three-dimensional roads according to the topological connectivity relationship; and
setting traffic markings at corresponding locations in the three-dimensional road according to the traffic marking attributes of the nodes of the plurality of paths.

7. An electronic device, comprising a memory and one or more programs, the one or more programs being stored in the memory and configured to be executed by one or more processors and causing the electronic device to perform a three-dimensional road network construction method, the method including:
obtaining a two-dimensional road network, the two-dimensional road network comprising a plurality of paths, each path being formed by connecting a plurality of nodes;
determining a relative elevation for a node of a current path overlapping the current path and/or another path among the nodes of the current path, the relative elevation representing a height of the current path at the node from a reference plane;
determining relative elevations of nodes constituting a center line of the current path according to the relative elevations of the nodes of the current path and a width of the current path; and
constructing a three-dimensional road corresponding to the current path according to the width of the current path and the relative elevations of the nodes of the center line of the current path to obtain a three-dimensional road network.

8. The electronic device according to claim 7, wherein the method further comprises:
determining an endpoint node in the current path for connection to another path; and
when a relative elevation of the endpoint node is less than a relative elevation of an endpoint node of the another path for connection, setting the relative elevation of the endpoint node of the path to the relative elevation of the endpoint node of the another path for connection; or
when a relative elevation of the endpoint node is greater than a relative elevation of an endpoint node of the another path for connection, setting the relative elevation of the endpoint node of the another path for connection to the relative elevation of the endpoint node of the path.

9. The electronic device according to claim 7, wherein before the determining relative elevations of nodes constituting a center line of the current path, the method further comprises:
merging two paths belonging to an upward and downward path category among all the paths into one path.

10. The electronic device according to claim 7, wherein the method further comprises:
adjusting relative elevations of nodes of the current path, wherein the adjusted relative elevations form a longitudinal slope of the current path that is less than or equal to a maximum longitudinal slope.

11. The electronic device according to claim 10, wherein the adjusting relative elevations of nodes of the current path further comprises:
reducing a relative elevation of a target node with a largest relative elevation in the current path, and increasing relative elevations of other nodes in the current path, wherein a node closer to the target node has a more increased relative elevation than the other nodes.

12. The electronic device according to claim 7, wherein after the constructing a three-dimensional road corresponding to the current path according to the width of the current path and the relative elevations of the nodes of the center line of the current path to obtain a three-dimensional road network, the method further comprises:
obtaining a topological connectivity relationship between the plurality of paths and traffic marking attributes of the nodes of the plurality of paths;
connecting the three-dimensional roads according to the topological connectivity relationship; and
setting traffic markings at corresponding locations in the three-dimensional road according to the traffic marking attributes of the nodes of the plurality of paths.

13. A non-transitory computer-readable storage medium, storing instructions, the instructions, when executed by one or more processors of an electronic device, causing the electronic device to perform a three-dimensional road network construction method, the method including:
obtaining a two-dimensional road network, the two-dimensional road network comprising a plurality of paths, each path being formed by connecting a plurality of nodes;
determining a relative elevation for a node of a current path overlapping the current path and/or another path among the nodes of the current path, the relative elevation representing a height of the current path at the node from a reference plane;
determining relative elevations of nodes constituting a center line of the current path according to the relative elevations of the nodes of the current path and a width of the current path; and
constructing a three-dimensional road corresponding to the current path according to the width of the current path and the relative elevations of the nodes of the center line of the current path to obtain a three-dimensional road network.

14. The non-transitory computer-readable storage medium according to claim 13, wherein the method further comprises:
determining an endpoint node in the current path for connection to another path; and
when a relative elevation of the endpoint node is less than a relative elevation of an endpoint node of the another path for connection, setting the relative elevation of the endpoint node of the path to the relative elevation of the endpoint node of the another path for connection; or
when a relative elevation of the endpoint node is greater than a relative elevation of an endpoint node of the another path for connection, setting the relative elevation of the endpoint node of the another path for connection to the relative elevation of the endpoint node of the path.

15. The non-transitory computer-readable storage medium according to claim 13, wherein before the determining relative elevations of nodes constituting a center line of the current path, the method further comprises:
merging two paths belonging to an upward and downward path category among all the paths into one path.

16. The non-transitory computer-readable storage medium according to claim 13, wherein the method further comprises:
adjusting relative elevations of nodes of the current path, wherein the adjusted relative elevations form a longitudinal slope of the current path that is less than or equal to a maximum longitudinal slope.

17. The non-transitory computer-readable storage medium according to claim 16, wherein the adjusting relative elevations of nodes of the current path further comprises:
reducing a relative elevation of a target node with a largest relative elevation in the current path, and increasing relative elevations of other nodes in the current path, wherein a node closer to the target node has a more increased relative elevation than the other nodes.

18. The non-transitory computer-readable storage medium according to claim 13, wherein after the constructing a three-dimensional road corresponding to the current path according to the width of the current path and the relative elevations of the nodes of the center line of the current path to obtain a three-dimensional road network, the method further comprises:
obtaining a topological connectivity relationship between the plurality of paths and traffic marking attributes of the nodes of the plurality of paths;
connecting the three-dimensional roads according to the topological connectivity relationship; and
setting traffic markings at corresponding locations in the three-dimensional road according to the traffic marking attributes of the nodes of the plurality of paths.
